(19) United States
(12) Patent Application Publication
(10) Pub. No.: US 2025/0081645 A1
(43) Pub. Date: Mar. 6, 2025

(54) IMAGE SENSOR

(71) Applicant: Samsung Electronics Co., Ltd., Suwon-si (KR)

(72) Inventor: Jungwook LIM, Suwon-si (KR)

(73) Assignee: Samsung Electronics Co., Ltd., Suwon-si (KR)

(21) Appl. No.: 18/661,946

(22) Filed: May 13, 2024

(30) Foreign Application Priority Data
Aug. 28, 2023 (KR) 10-2023-0112852

(51) Int. Cl. H01L 27/146; H01L 23/00; H01L 23/522

(52) U.S. Cl. CPC H10F 39/80373; H01L 23/5223; H01L 24/08; H10F 39/182; H10F 39/807; H10F 39/809; H10F 39/811; H01L 2224/08145

(57) ABSTRACT

Disclosed is an image sensor comprising a first semiconductor substrate that includes a first pixel region and a second pixel region, a first photoelectric conversion element on the first pixel region, a second photoelectric conversion element on the second pixel region, a first floating diffusion section on the first pixel region, a second floating diffusion section on the second pixel region, a first transfer gate electrode between the first photoelectric conversion element and the first floating diffusion section, a second transfer gate electrode between the second photoelectric conversion element and the second floating diffusion section, a second semiconductor substrate on the first semiconductor substrate, and pixel transistors connected to the first and second photoelectric conversion elements. A width of the second photoelectric conversion element is less than that of the first photoelectric conversion element. At least one of the pixel transistors is on the second semiconductor substrate.

### CROSS-REFERENCE TO RELATED APPLICATION

This U.S. nonprovisional application claims priority under 35 U.S.C § 119 to Korean Patent Application No. 10-2023-0112852 filed on Aug. 28, 2023 in the Korean Intellectual Property Office, the disclosure of which is hereby incorporated by reference in its entirety.

### BACKGROUND

### Field of the Disclosure

The present inventive concepts relate to an image sensor, and more particularly, to an image having small pixels while maintaining high dynamic ranges.

### Description of Related Art

An image sensor converts photonic images into electrical signals. Recent advances in computer and communication industries have led to strong demands in high performance image sensors in various consumer electronic devices such as digital cameras, camcorders, PCSs (personal communication systems), game consoles, security cameras, and medical micro-cameras. Image sensors are commonly classified as either charged coupled device (CCD) sensors or CMOS image sensors. A CMOS image sensor has a comparatively simple operating method, and a size of its product is possibly minimized because its signal processing circuit is integrated into a single chip. Also, the CMOS image sensor requires relatively small power consumption, which is useful in battery-powered applications. In addition, since process technology for manufacturing CMOS image sensors is compatible with CMOS process technology, the CMOS image sensors may reduce fabrication costs. Accordingly, the use of the CMOS image sensor has been rapidly increasing as a result of advances in technology, and implementation of high resolution devices.

### SUMMARY

Some example embodiments provide an image sensor having small pixels while securing dynamic ranges.

Objects of the present example embodiments are not limited to the one mentioned above, and other objects which have not been mentioned above will be clearly understood by those skilled in the art from the following description.

According to some example embodiments, an image sensor may comprise: a first semiconductor substrate that includes a first pixel region and a second pixel region; a first photoelectric conversion element on the first pixel region; a second photoelectric conversion element on the second pixel region; a first floating diffusion section on the first pixel region; a second floating diffusion section on the second pixel region; a first transfer gate electrode between the first photoelectric conversion element and the first floating diffusion section; a second transfer gate electrode between the second photoelectric conversion element and the second floating diffusion section; a second semiconductor substrate on the first semiconductor substrate; and a plurality of pixel transistors connected to the first and second photoelectric conversion elements. A width of the second photoelectric conversion element may be less than a width of the first photoelectric conversion element. At least one of the plurality of pixel transistors may be on the second semiconductor substrate.

According to some example embodiments, an image sensor may comprise: a photoelectric conversion circuit layer that includes first and second photoelectric conversion elements on a first semiconductor substrate; a pixel circuit layer that includes a second semiconductor substrate and is on the photoelectric conversion circuit layer; and a logic circuit layer on the pixel circuit layer and including logic circuits on a third semiconductor substrate. The photoelectric conversion circuit layer may include: a dual conversion gain transistor on the first semiconductor substrate and connected between a first floating diffusion section and a third floating diffusion section; a source follower transistor on the first semiconductor substrate and connected to the first floating diffusion section; a first transfer gate electrode between the first photoelectric conversion element and the first floating diffusion section; and a second transfer gate electrode between the second photoelectric conversion element and a second floating diffusion section. The pixel circuit layer may include: a reset transistor on the second semiconductor substrate and connected to the third floating diffusion section; a first switching transistor on the second semiconductor substrate and connected to the dual conversion gain transistor; and a second switching transistor on the second semiconductor substrate and connected to the second floating diffusion section. A width of the second photoelectric conversion element may be less than a width of the first photoelectric conversion element.

According to some example embodiments, an image sensor may comprise: a photoelectric conversion circuit layer that includes first and second photoelectric conversion elements on a first semiconductor substrate; a pixel circuit layer that includes a second semiconductor substrate and is on the photoelectric conversion circuit layer; and a logic circuit layer on the pixel circuit layer and including logic circuits on a third semiconductor substrate. The photoelectric conversion circuit layer may include: a first transfer gate electrode between the first photoelectric conversion element and the first floating diffusion section; and a second transfer gate electrode between the second photoelectric conversion element and the second floating diffusion section. The pixel circuit layer may include: a dual conversion gain transistor on the second semiconductor substrate and connected between the first floating diffusion section and a third floating diffusion section; a source follower transistor on the second semiconductor substrate; a reset transistor on the second semiconductor substrate and connected to the third floating diffusion section; a first switching transistor on the second semiconductor substrate and connected to the dual conversion gain transistor; a second switching transistor on the second semiconductor substrate and connected to the second floating diffusion section; and a third switching transistor on the second semiconductor substrate and connected to the source follower transistor and the first floating diffusion section. A width of the second photoelectric conversion element may be less than a width of the first photoelectric conversion element.

### BRIEF DESCRIPTION OF DRAWINGS

FIG. 1 illustrates a block diagram showing an image sensor according to some example embodiments.

FIGS. 2A and 2B illustrate simplified perspective views showing an image sensor according to some example embodiments.

FIGS. 3A and 3B illustrate circuit diagrams showing a unit pixel of a pixel array according to some example embodiments.

FIG. 4A illustrates a plan view showing an example of a unit pixel having a circuit configuration shown in FIG. 3A.

FIG. 4B illustrates a plan view showing an example of a unit pixel having a circuit configuration shown in FIG. 3B.

FIGS. 5A to 6 illustrate cross-sectional views showing an image sensor according to some example embodiments.

FIG. 7 illustrates a plan view showing an image sensor according to some example embodiments.

FIG. 8 illustrates a timing diagram showing an operation of an image sensor according to some example embodiments.

FIGS. 9A and 9B illustrate cross-sectional views showing an image sensor according to some example embodiments.

### DETAILED DESCRIPTION OF EXAMPLE EMBODIMENTS

Various example embodiments are described below with reference to the accompanying drawings. Like reference numerals may indicate like components throughout the description.

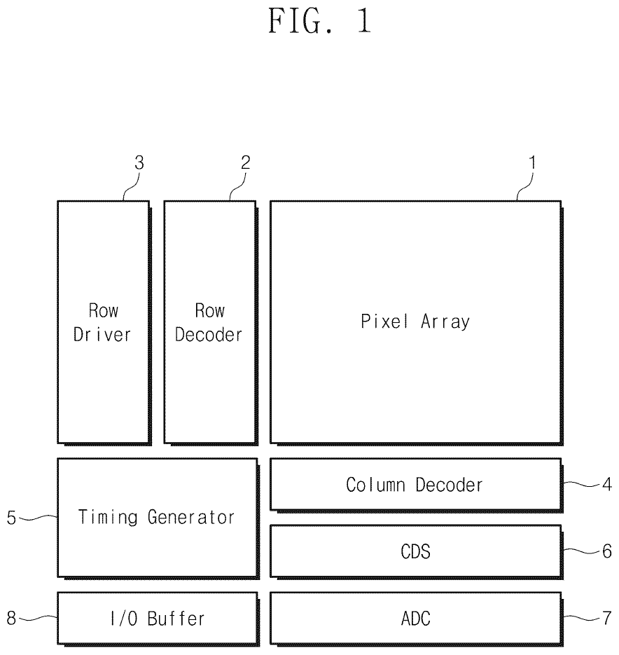

FIG. 1 illustrates a block diagram showing an image sensor according to some example embodiments.

Referring to FIG. 1, an image sensor may include an active pixel sensor array (or pixel array) 1, a row decoder 2, a row driver 3, a column decoder 4, a timing generator 5, a correlated double sampler (CDS) 6, an analog-to-digital converter (ADC) 7, and an input/output buffer 8.

The active pixel sensor array 1 may include a plurality of two-dimensionally arranged unit pixels, each of which is configured to convert optical signals into electrical signals. The active pixel sensor array 1 may be driven by a plurality of driving signals such as a pixel selection signal, a reset signal, and a charge transfer signal from the row driver 3. The converted electrical signals may be provided for the correlated double sampler 6.

The row driver 3 may provide the active pixel sensor array 1 with several driving signals for driving several unit pixels in accordance with a decoded result obtained from the row decoder 2. When the unit pixels are arranged in a matrix shape, the driving signals may be provided for each row.

The timing generator 5 may provide the row and column decoders 2 and 4 with timing and control signals.

The correlated double sampler 6 may receive the electrical signals generated in the active pixel sensor array 1, and hold and sample the received electrical signals. The correlated double sampler 6 may perform a double sampling operation to sample a specific noise level and a signal level of the electrical signal, and then output a difference level corresponding to a difference between the noise and signal levels.

The analog-to-digital converter 7 may convert analog signals, which correspond to the difference level received from the correlated double sampler 6, into digital signals, and then output the converted digital signals.

The input/output buffer 8 may latch the digital signals and may sequentially output the latched digital signals to an image signal processor (not shown) in response to the decoded result obtained from the column decoder 4.

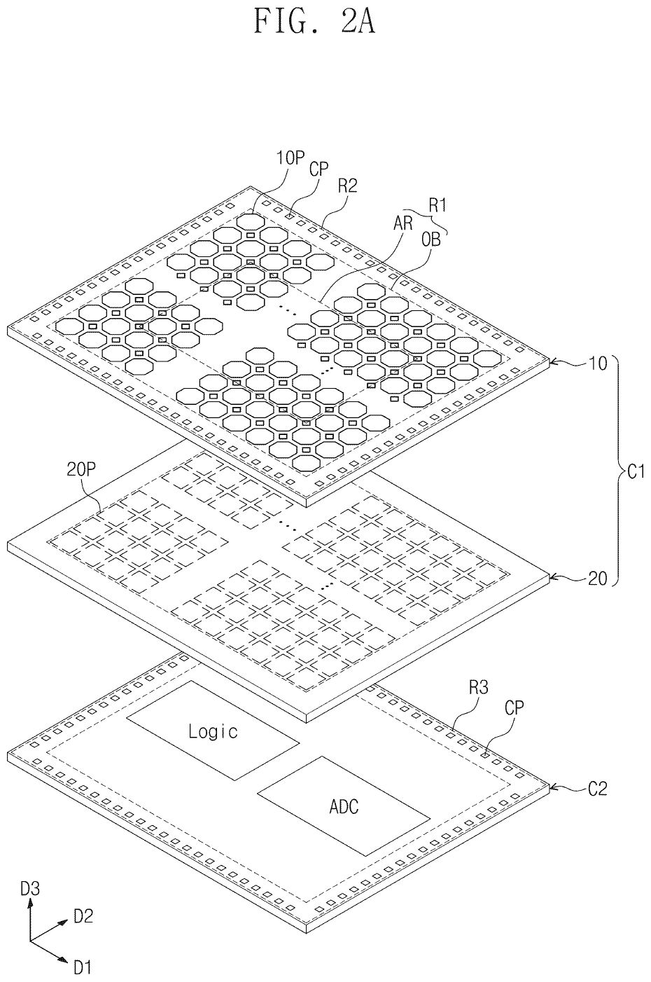

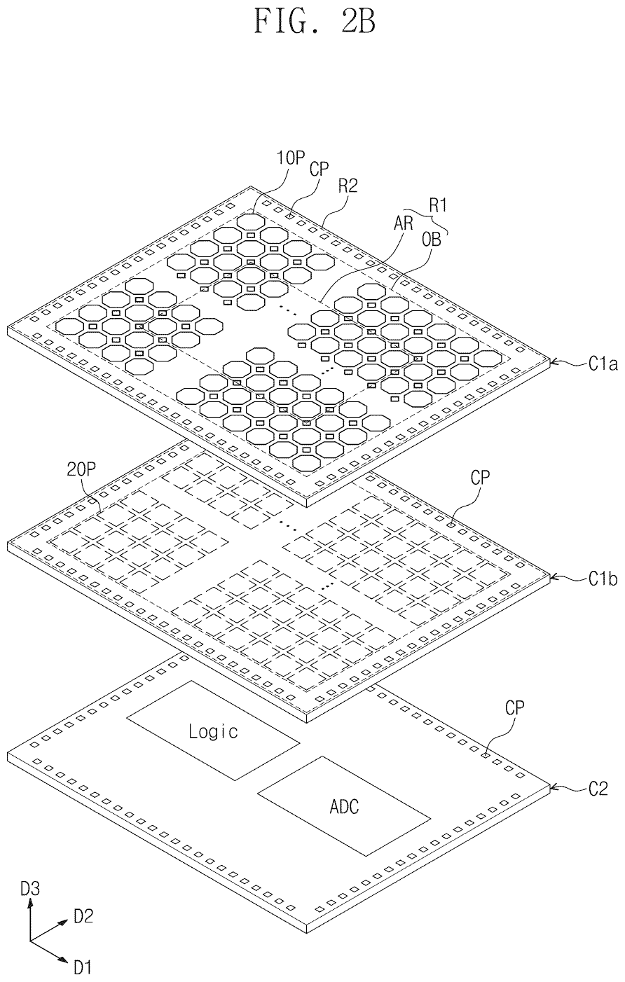

FIGS. 2A and 2B illustrate simplified perspective views showing an image sensor according to some example embodiments.

Referring to FIG. 2A, an image sensor may include a sensor chip C1 and a logic chip C2.

The sensor chip C1 may convert images of external substances into electrical signals or data signals. The sensor chip C1 may include a pixel array (see 1 of FIG. 1) discussed above with reference to FIG. 1. For example, the sensor chip C1 may include a plurality of unit pixels, and as discussed below with reference to FIGS. 2A and 2B, each of the unit pixels may include a photoelectric conversion circuit 10P and a pixel circuit 20P.

The sensor chip C1 may include a pixel array zone R1 and a pad zone R2. The pixel array zone R1 may include a plurality of unit pixels that are two-dimensionally arranged along a first direction D1 and a second direction D2 that intersect each other. Each unit pixel of the pixel array zone R1 may output an electrical signal generated from incident light.

The pixel array zone R1 may include a light-receiving region AR and a light-shielding region OB. When viewed in plan, a light-shielding region OB may surround the light-receiving region AR. For example, when viewed in plan, the light-shielding region OB may be disposed on upside, downside, left-side, and right-side of the light-receiving region AR. The light-shielding region OB may include reference pixels on which no light is incident, and amounts of charge sensed in the unit pixels of the light-receiving region AR may be compared with reference amounts of charge occurring at reference pixels, which may result in calculation of magnitude of electrical signals sensed in the unit pixels.

The pad zone R2 may include a plurality of conductive pads CP used for input and output of control signals and photoelectric conversion signals. For easy connection with external devices, when viewed in plan, the pad zone R2 may surround the pixel array zone R1. Electrical signals may be transmitted through the conductive pads CP between the unit pixels and an external device.

The sensor chip C1 may include a photoelectric conversion circuit layer 10, a pixel circuit layer 20, and an optical transmission layer (not shown). When viewed in cross-section, the pixel circuit layer 20 may be disposed between the photoelectric conversion circuit layer 10 and the optical transmission layer. The pixel circuit layer 20 may be adjacent to the logic chip C2.

The sensor chip C1 may include pixel transistors, and the pixel transistors may be disposed distributed on the photoelectric conversion circuit layer 10 and the pixel circuit layer 20. The present example embodiments, however, are not limited thereto, and the pixel transistors may be disposed only on the pixel circuit layer 20.

The photoelectric conversion circuit layer 10 may include a first semiconductor substrate (not shown) and photoelectric conversion circuits 10P. The photoelectric conversion circuits 10P may include first and second transfer transistors (not shown), and may additionally include some of the pixel transistors provided on the first semiconductor substrate. The photoelectric conversion circuits 10P may be two-dimensionally arranged along first direction D1 and the second direction D2 that intersect each other.

The pixel circuit layer 20 may include a second semiconductor substrate (not shown) and pixel circuits 20P. The pixel circuits 20P may include at least some of the pixel transistors provided on the second semiconductor substrate.

The logic chip C2 may include logic circuits (see 2, 3, 4, 5, 6, 7, and 8 of FIG. 1), a power circuit, an input/output interface, and/or an image signal processor. For example, the logic chip C2 may include components other than the pixel array 1 of the image sensor depicted in FIG. 1. The logic chip C2 may include, for example, the row decoder 2, the row driver 3, the column decoder 4, the timing generator 5, the correlated double sampler 6, the analog-to-digital converter 7, and the input/output buffer 8.

The logic chip C2 may include a logic pad zone R3 that corresponds to the pad zone R2 of the sensor chip C1. The logic pad zone R3 may include a plurality of conductive pads CP used for input/output of control signals. The conductive pads CP of the sensor chip C1 may be electrically connected to the conductive pads CP of the logic chip C2. The logic chip C2 may be bonded to the sensor chip C1 so as to adjoin the pixel circuit layer 20 of the sensor chip C1.

Referring to FIG. 2B, an image sensor may include a first chip C1a including photoelectric conversion circuits 10P of a plurality of unit pixels, a second chip C1b including pixel circuits 20P of a plurality of unit pixels, and a logic chip C2.

The first chip C1a may include a pixel array zone R1 and a pad zone R2, and the pixel array zone R1 may include a light-receiving region AR and a light-shielding region OB. The first chip C1a may include photoelectric conversion circuits 10P of a plurality of unit pixels. The photoelectric conversion circuits 10P may be two-dimensionally arranged along the first direction D1 and the second direction D2 on the pixel array zone R1.

The second chip C1b may include pixel circuits 20P of a plurality of unit pixels. The pixel circuits 20P may be provided corresponding to the photoelectric conversion circuits 10P. The second chip C1b may include conductive pads CP corresponding to the conductive pads CP of the first chip C1a. The conductive pads CP of the first chip C1a may be electrically connected to the conductive pads CP of the second chip C1b.

As discussed above, the logic chip C2 may include logic circuits (see 2, 3, 4, 5, 6, 7, and 8 of FIG. 1), a power circuit, an input/output interface, and/or an image signal processor. The conductive pads CP of the logic chip C2 may be electrically connected to the conductive pads CP of the second chip C1b.

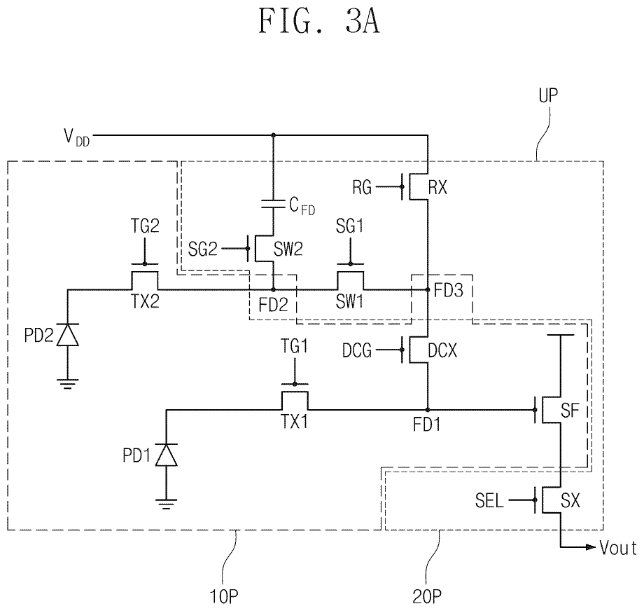

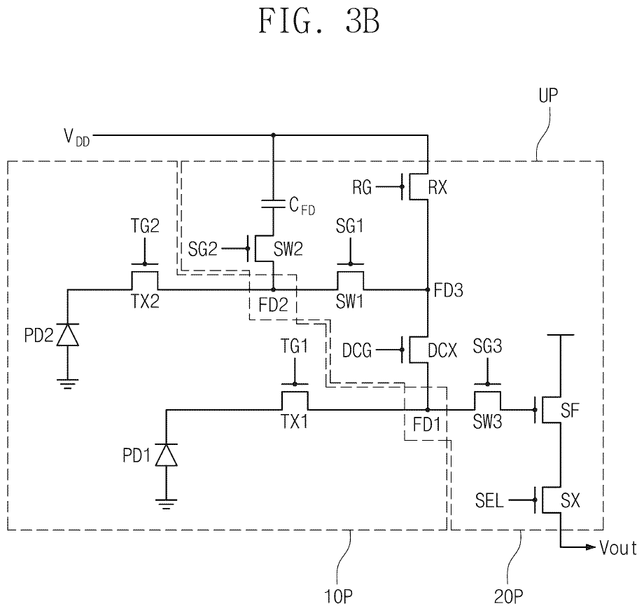

FIGS. 3A and 3B illustrate circuit diagrams showing a unit pixel of a pixel array according to some example embodiments.

Referring to FIG. 3A, a unit pixel UP may include a photoelectric conversion circuit 10P and a pixel circuit 20P.

The photoelectric conversion circuit 10P may include first and second photoelectric conversion elements PD1 and PD2, first and second transfer transistors TX1 and TX2, a dual conversion gain transistor DCX, a source follower transistor SF, and first, second, and third floating diffusion sections FD1, FD2, and FD3.

The pixel circuit 20P may include a selection transistor SX, a reset transistor RX, first and second switching transistors (or switching elements) SW1 and SW2, a capacitor (or a charge storage element) C_{FD}, and second and third floating diffusion sections FD2 and FD3.

A first semiconductor substrate (not shown) may be provided thereon with the first and second photoelectric conversion elements PD1 and PD2, the first and second transfer transistors TX1 and TX2, the dual conversion gain transistor DCX, and the source follower transistor SF that are included in the photoelectric conversion circuit 10P. In contrast, a second semiconductor substrate (not shown) may be provided thereon with the selection transistor SX, the reset transistor RX, the first and second switching transistors SW1 and SW2, and the capacitor C_{FD} that are included in the pixel circuit 20P.

In some embodiments, it is disclosed that each unit pixel UP includes six pixel transistors RX, DCX, SF, SX, SW1, and SW2, but the present example embodiments are not limited thereto, and the number of pixel transistors may be variously changed.

For example, the first and second photoelectric conversion elements PD1 and PD2 may generate and accumulate charges in proportion to an amount of incident light. The first and second photoelectric conversion elements PD1 and PD2 may each be one of a photo diode, a photo transistor, a photo gate, a pinned photo diode (PPD), or any combination thereof.

The first transfer transistor TX1 may allow the first floating diffusion section FD1 to receive charges accumulated in the first photoelectric conversion elements PD1.

The second transfer transistor TX2 may allow the second floating diffusion section FD2 to receive charges accumulated in the second photoelectric conversion elements PD2.

When the second transfer transistor TX2 is turned on, charges generated from the second photoelectric conversion element PD2 may be accumulated or stored in the capacitor C_{FD}.

The first and second transfer transistors TX1 and TX2 may be controlled with first and second transfer signals TG1 and TG2.

The first floating diffusion section FD1 may receive and accumulate stored charges generated from the first photoelectric conversion element PD1. The source follower transistor SF may be controlled in accordance with a number of photo-charges accumulated in the first floating diffusion section FD1.

The first switching transistor SW1 may be connected between the second floating diffusion section FD2 and the third floating diffusion section FD3. In response to a first switching signal SG1, the first switching transistor SW1 may change a capacitance of the first floating diffusion section FD1 to change a conversion gain of the unit pixel UP.

The second switching transistor SW2 may be connected between the capacitor (or the charge storage element) C_{FD} and the second floating diffusion section FD2. In response to a second switching signal SG2, the second switching transistor SW2 may change a capacitance of the second floating diffusion section FD2 to change a conversion gain of the unit pixel UP.

The capacitor C_{FD} may be connected between the second floating diffusion section FD2 and a pixel power voltage V_{DD}. The capacitor C_{FD} may be connected between the second switching transistor SW2 and the pixel power voltage V_{DD}. For example, the capacitor C_{FD} may be a metal-oxide-semiconductor (MOS) capacitor, a metal-insulator-semiconductor (MIS) capacitor, or a metal-insulator-metal (MIM) capacitor. In response to an amount of charge generated from the second photoelectric conversion element PD2 and an operation of the second transfer transistor TX2, the capacitor C_{FD} may store charges.

The dual conversion gain transistor DCX may be connected between the first floating diffusion section FD1 and the third floating diffusion section FD3. The dual conversion gain transistor DCX may be connected in series to the reset transistor RX through the third floating diffusion section FD3. For example, the dual conversion gain transistor DCX may be connected between the first floating diffusion section FD1 and the reset transistor RX. In response to a dual conversion gain control signal DCG, the dual conversion gain transistor DCX may change a capacitance of the first floating diffusion section FD1 to change a conversion gain of the unit pixel UP.

In response to a reset signal RG applied to a reset gate electrode, the reset transistor RX may periodically reset the charges accumulated in the first and third floating diffusion sections FD1 and FD3. A drain terminal of the reset transistor RX may be connected to the third floating diffusion section FD3, and a source terminal of the reset transistor RX may be connected to the pixel power voltage V_{DD}. For example, the reset transistor RX may be connected to the pixel power voltage V_{DD} and the dual conversion gain transistor DCX. When the reset transistor RX and the dual conversion gain transistor DCX are turned on, the pixel power voltage V_{DD} may be delivered to the first and third floating diffusion sections FD1 and FD3. Therefore, the charges accumulated in the first and third floating diffusion sections FD1 and FD3 may be discharged to rest the first and third floating diffusion sections FD1 and FD3.

In a plurality of pixels, the first, second, and third floating diffusion sections FD1, FD2, and FD3 may accumulate charges generated from the first and second photoelectric conversion elements PD1 and PD2 such as photodiodes, and the charged accumulated in the first, second, and third floating diffusion sections FD1, FD2, and FD3 may be converted into a voltage. A conversion gain may be defined to refer to a ratio at which the charges accumulated in the floating diffusion sections FD1, FD2, and FD3 are converted into a voltage, and the conversion gain may be changed in accordance with capacitance of the floating diffusion sections FD1, FD2, and FD3.

For example, an increase in capacitance of the floating diffusion sections FD1, FD2, and FD3 may cause a reduction in conversion gain, and a reduction in capacitance of the floating diffusion sections FD1, FD2, and FD3 may cause an increase in conversion gain. In some example embodiments, each pixel may operate in a dual gain mode (dual conversion gain). The dual conversion gain mode may include a first conversion gain mode (or low conversion gain (LCG)) and a second conversion gain mode (or high conversion gain (HCG)). A ratio at which a charge is converted into a voltage may be greater in the second conversion gain mode than in the first conversion gain mode. For example, in response to low illumination, the second conversion gain mode may be applied to an operation of generation of pixel signals.

The first conversion gain mode or the second conversion gain mode may operate based on an operation of the dual conversion gain transistor DCX.

When the dual conversion gain transistor DCX is turned off, the first floating diffusion section FD1 may have a small capacitance, and the unit pixel UP may operate in the first conversion gain mode.

When the dual conversion gain transistor DCX is turned on, the first floating diffusion section FD1 and the second floating diffusion section FD2 may be connected to increase a capacitance of the first and second floating diffusion sections FD1 and FD2. For example, when the dual conversion gain transistor DCX is turned on, the unit pixel UP may operate in the second conversion gain mode.

For example, when the dual conversion gain transistor DCX is turned on, a capacitance of the first floating diffusion section FD1 or the second floating diffusion section FD2 may increase to reduce a conversion gain, and when the dual conversion gain transistor DCX is turned off, a capacitance of the first floating diffusion section FD1 may decrease to increase a conversion gain.

First to fourth pixel signals generated through a dual conversion gain mode of each of the first and second photoelectric conversion elements PD1 and PD2 may be synthesized into one image, and the synthesized image may have a high dynamic range.

The source follower transistor SF may be a source follower buffer amplifier that generates a source-drain current in proportion to an amount of charge applied to a source follower gate electrode from the first floating diffusion section FD1. The source follower transistor SF may amplify a variation in electrical potential of the first floating diffusion section FD1 and may output the amplified signal to an output line V_{OUT} through the selection transistor SX. A source terminal of the source follower transistor SF may be connected to the pixel power voltage V_{DD}, and a drain terminal of the source follower transistor SF may be connected to a source terminal of the selection transistor SX.

The selection transistor SX may select each row of the unit pixel UP to be readout. When the selection transistor SX is turned on in response to a selection signal SEL applied to a selection gate electrode, the output line V_{OUT} may output an electrical signal that is output from the drain terminal of the source follower transistor SF.

Referring to FIG. 3B, the photoelectric conversion circuit 10P may include first and second photoelectric conversion elements PD1 and PD2, first and second transfer transistors TX1 and TX2, and a first floating diffusion section FD1.

The pixel circuit 20P may include a dual conversion gain transistor DCX, a source follower transistor SF, a selection transistor SX, a reset transistor RX, first, second, and third switching transistors (or switching elements) SW1, SW2, and SW3, a capacitor (or a charge storage element) C_{FD}, and second and third floating diffusion sections FD2 and FD3.

A first semiconductor substrate (not shown) may be provided thereon with the first and second transfer transistors TX1 and TX2 and the first and second photoelectric conversion elements PD1 and PD2 that are included in the photoelectric conversion circuit 10P. In contrast, a second semiconductor substrate (not shown) may be provided thereon with the dual conversion gain transistor DCX, the source follower transistor SF, the selection transistor SX, the reset transistor RX, the first, second, and third switching transistors SW1, SW2, and SW3, and the capacitor C_{FD} that are included in the pixel circuit 20P.

The unit pixel UP may further includes a third switching transistor SW3 connected between the first floating diffusion section FD1 and the source follower transistor SF. An amount of charge generated from the first photoelectric conversion element PD1 may be accumulated in a source/drain terminal of the third switching transistor SW3.

In some embodiments, it is disclosed that each unit pixel UP includes seven pixel transistors RX, DCX, SF, SX, SW1, SW2, and SW3, but the present example embodiments are not limited thereto and the number of pixel transistors may be variously changed.

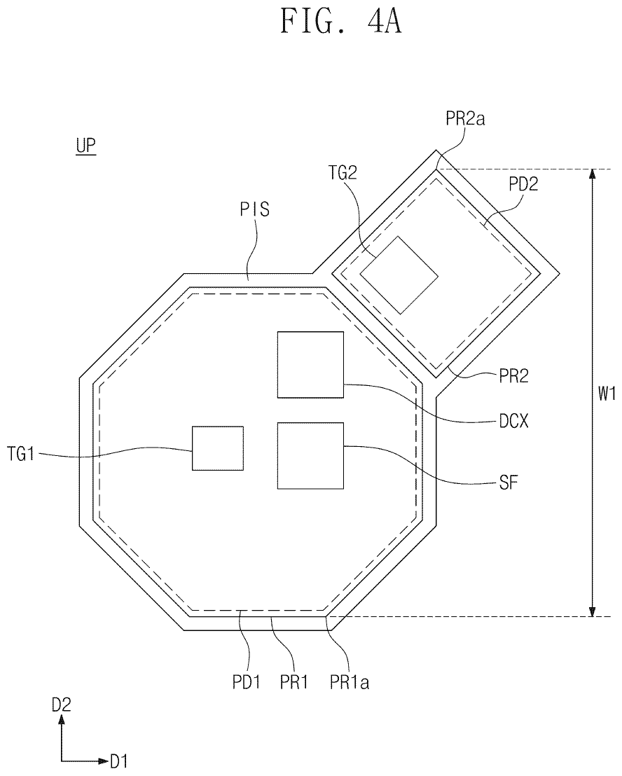

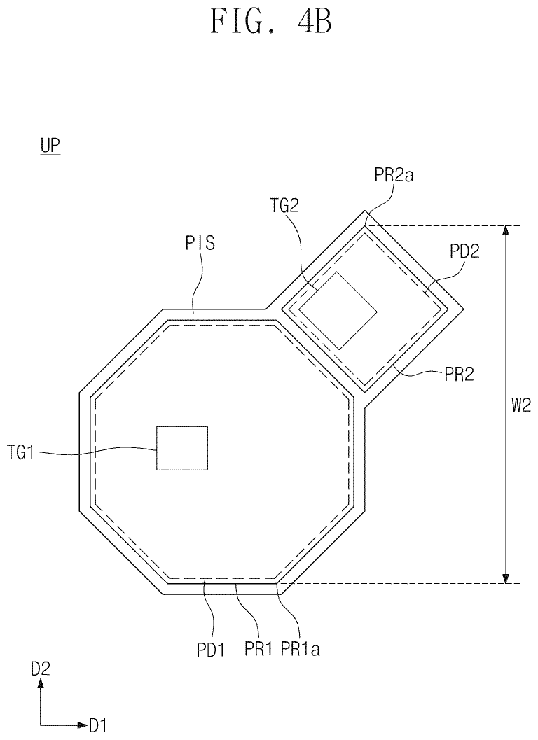

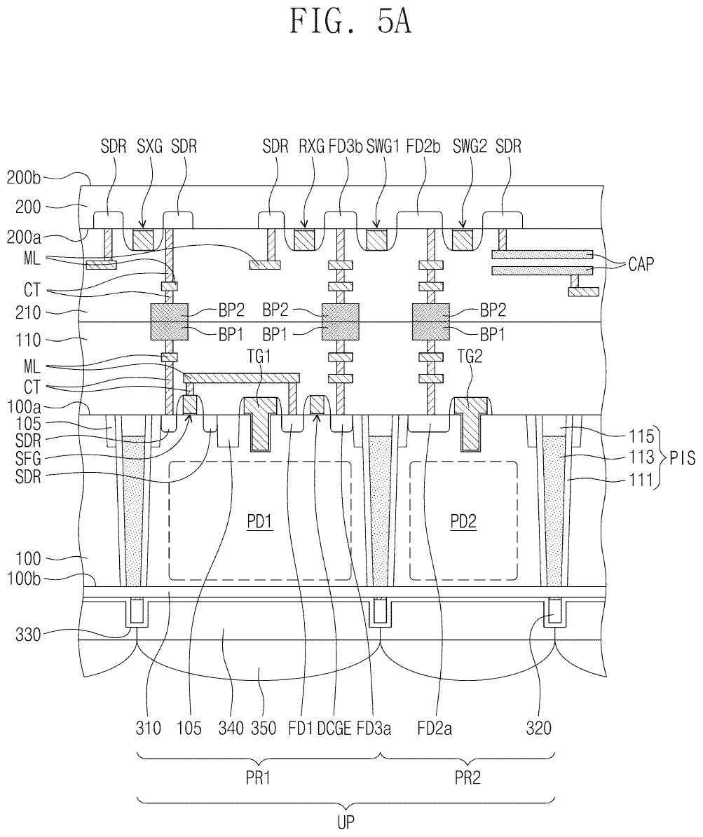

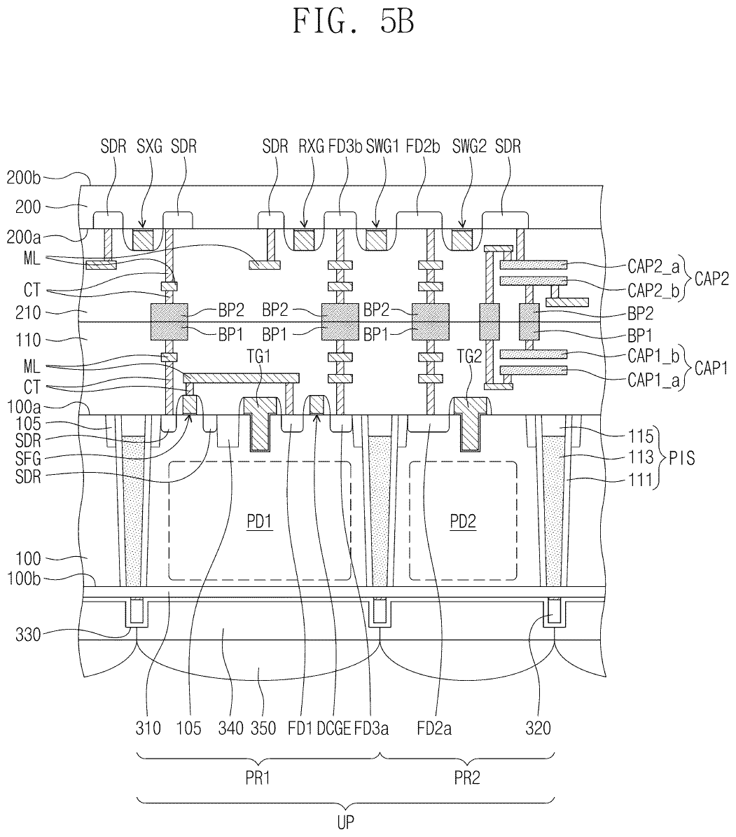

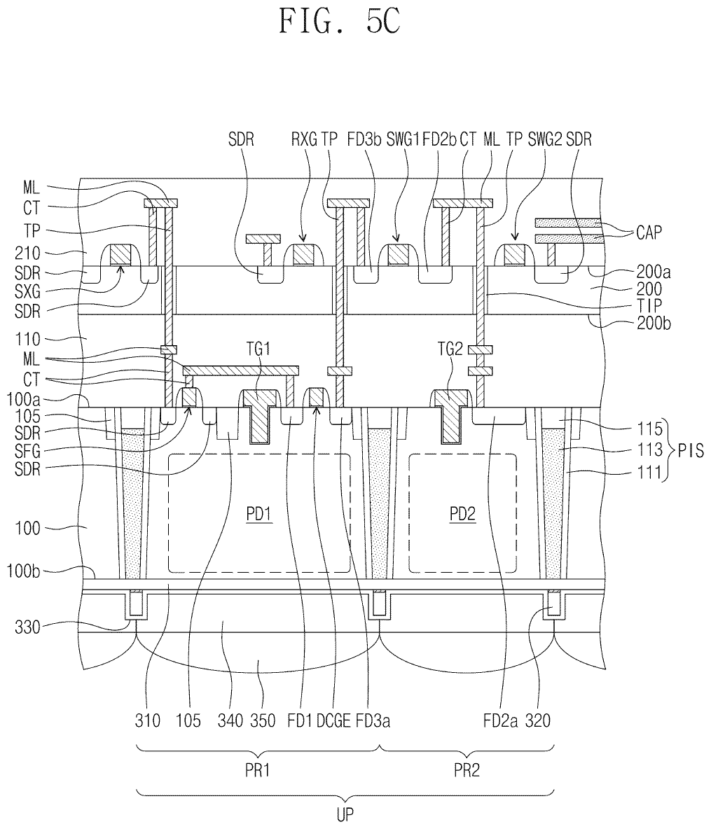

FIG. 4A illustrates a plan view showing an example of a unit pixel having a circuit configuration shown in FIG. 3A. FIG. 5A illustrate a cross-sectional view showing an image sensor according to some example embodiments.

Referring to FIGS. 3A, 4A, and 5A, an image sensor may include a plurality of unit pixels UP, and each unit pixel UP may include first and second pixel regions PR1 and PR2. The first and second pixel regions PR1 and PR2 may be two-dimensionally arranged along rows and columns. When viewed in plan, each of the first and second pixel regions PR1 and PR2 may be surrounded by a pixel isolation structure PIS.

The first pixel region PR1, or a first photoelectric conversion element PD1, may have an octagonal shape when viewed in plan. The second pixel region PR2, or a second photoelectric conversion element PD2, may have a tetragonal shape when viewed in plan, and may be adjacent to one of lateral surfaces of the first pixel region PR1. The planar shapes of the first and second pixel regions PR1 and PR2 are not limited thereto and may be variously changed.

The first pixel region PR1 may be provided thereon with a first transfer gate electrode TG1, a source follower transistor SF, and a dual conversion gain transistor DCX, and the second pixel region PR2 may be provided thereon with a second transfer gate electrode TG2. For example, a first semiconductor substrate 100 may be provided thereon with the first and second transfer gate electrodes TG1 and TG2, the source follower transistor SF, and the dual conversion gain transistor DCX, and a second semiconductor substrate 200 may be provided thereon with remaining pixel transistors.

According to some example embodiments, at least some of the pixel transistors may be disposed not on the first semiconductor substrate 100, but on the second semiconductor substrate 200, and thus the unit pixel UP may have a reduced size. A length W1 in the second direction D2 of the unit pixel UP may be equal to or less than about 2.4 μm, for example, equal to or less than about 2.1 μm. The length W1 in the second direction D2 of the unit pixel UP may indicate a distance in the second direction D2 between vertices positioned on opposite ends along the second direction D2 in the unit pixel UP. For example, referring to FIG. 4A, the length W1 in the second direction D2 may indicate a distance in the second direction D2 between a vertex PR1a (a lowermost end point in the second direction D2) of the first pixel region PR1 and a vertex PR2a (an uppermost end point in the second direction D2) of the second pixel region PR2.

The first semiconductor substrate 100 may have a first top surface (or a front surface) 100a and a second surface 100b (or a rear surface) 100b that are opposite to each other, and the second semiconductor substrate 200 may have a first top surface (or a front surface) 200a and a second surface 200b (or a rear surface) 200b that are opposite to each other. The first and second semiconductor substrates 100 and 200 may be a substrate in which an epitaxial layer is formed on a bulk silicon substrate having the same first conductivity type (e.g., p-type) as that of the epitaxial layer, or a substrate formed of only a p-type epitaxial layer from which a bulk silicon substrate is removed in fabrication of the image sensor. Alternatively, the first and second semiconductor substrates 100 and 200 may be a bulk semiconductor substrate that includes a well of the first conductivity type.

A pixel isolation structure PIS may be disposed in the first semiconductor substrate 100, and may define the first and second pixel regions PR1 and PR2. The pixel isolation structure PIS may be provided between the first and second pixel regions PR1 and PR2 of the first semiconductor substrate 100. When viewed in plan, the pixel isolation structure PIS may surround each of the first and second pixel regions PR1 and PR2.

The pixel isolation structure PIS may have a top surface substantially coplanar with the first surface 100a of the first semiconductor substrate 100. The pixel isolation structure PIS may extend from the first surface 100a to the second surface 100b.

The pixel isolation structure PIS may be formed by patterning the first surface 100a of the first semiconductor substrate 100 to form a deep trench, and then filling the deep trench with a liner dielectric layer and an impurity-doped semiconductor layer. In this case, the pixel isolation structure PIS may have a width that gradually decreases in a direction from the first surface 100a toward the second surface 100b of the first semiconductor substrate 100. Alternatively, the pixel isolation structure PIS may have a width that is substantially constant between the first surface 100a and the second surface 100b of the first semiconductor substrate 100.

The pixel isolation structure PIS may be formed by patterning the second surface 100b of the first semiconductor substrate 100 to form a deep trench, and then filling the deep trench with a liner dielectric layer and an impurity-doped semiconductor layer. In this case, the pixel isolation structure PIS may have a width that gradually increases in a direction from the first surface 100a toward the second surface 100b of the first semiconductor substrate 100.

The pixel isolation structure PIS may be formed of a dielectric material whose refractive index is less than that of the first semiconductor substrate 100 (e.g., silicon) and may include a single or a plurality of dielectric layers.

The pixel isolation structure PIS may include a liner dielectric pattern 111, a semiconductor pattern 113, and a capping dielectric pattern 115. The semiconductor pattern 113 may vertically penetrate a portion of the first semiconductor substrate 100, and the liner dielectric pattern 111 may be provided between the semiconductor pattern 113 and the first semiconductor substrate 100. The capping dielectric pattern 115 may be disposed on the semiconductor pattern 113, and may have a top surface substantially coplanar with the first surface 100a of the first semiconductor substrate 100. The liner dielectric pattern 111 and the capping dielectric pattern 115 may include at least one selected from a silicon oxide layer, a silicon oxynitride layer, and a silicon nitride layer. The semiconductor pattern 113 may include an undoped polysilicon layer or an impurity-doped polysilicon layer. The semiconductor pattern 113 may have an air gap or a void.

The pixel isolation structure PIS may penetrate the first semiconductor substrate 100. The pixel isolation structure PIS may vertically extend from the first surface 100a to the second surface 100b of the first semiconductor substrate 100. For example, the pixel isolation structure PIS may have a vertical length in a direction perpendicular to a surface of the first semiconductor substrate 100, and the vertical length may be substantially the same as a vertical thickness of the first semiconductor substrate 100. Alternatively, the pixel isolation structure PIS may vertically penetrate a portion of the first semiconductor substrate 100, and may be spaced apart from the second surface 100b of the first semiconductor substrate 100.

The pixel isolation structure PIS may prevent the first and second pixel regions PR1 and PR2 from receiving randomly drifting photo-charges that are generated from light that is incident on the first and second pixel regions PR1 and PR2. In this configuration, the pixel isolation structure PIS may help prevent crosstalk between neighboring first and second pixel regions PR1 and PR2.

According to some embodiments, the first photoelectric conversion element PD1 may be provided in the first semiconductor substrate 100 on the first pixel region PR1. The second photoelectric conversion element PD2 may be provided in the first semiconductor substrate 100 on the second pixel region PR2. The first and second photoelectric conversion elements PD1 and PD2 may convert externally incident light into electrical signals.

Each of the first and second photoelectric conversion elements PD1 and PD2 may be doped with impurities having a second conductivity type (e.g., n-type) opposite to that of the first semiconductor substrate 100. Photodiodes may be constituted by the first semiconductor substrate 100 of the first conductivity type and the first and second photoelectric conversion elements PD1 and PD2. For example, a photodiode may be constituted by a junction between the first semiconductor substrate 100 of the first conductivity type and one of the first and second photoelectric conversion elements PD1 and PD2 of the second conductivity type. The first and second photoelectric conversion elements PD1 and PD2 that constitute the photodiodes may generate and accumulate photo-charges in proportion to intensity of incident light.

In some embodiments, the first photoelectric conversion element PD1 may have a light-receiving area greater than that of the second photoelectric conversion element PD2. For example, the first photoelectric conversion element PD1 may have a volume greater than that of the second photoelectric conversion element PD2. The first and second photoelectric conversion elements PD1 and PD2 may have substantially the same vertical depth, and a width of the first photoelectric conversion element PD1 may be less than that of the second photoelectric conversion element PD2.

When viewed in plan, each of the first and second photoelectric conversions elements PD1 and PD2 may be surrounded by the pixel isolation structure PIS. Therefore, photo-charges accumulated in the first and second photoelectric conversion elements PD1 and PD2 may be prevented from overflowing into their adjacent first and second photoelectric conversion elements PD1 and PD2.

On each of the first and second pixel regions PR1 and PR2, a device isolation layer 105 may define at least one active section on the first surface 100a of the first semiconductor substrate 100.

On each of the pixel regions PR1 and PR2, the device isolation layer 105 may be disposed adjacent to the first surface 100a of the first semiconductor substrate 100. A bottom surface of the device isolation layer 105 may be spaced apart from the first and second photoelectric conversion elements PD1 and PD2.

The device isolation layer 105 may be provided in a trench formed by recessing the first surface 100a of the first semiconductor substrate 100. The device isolation layer 105 may be formed of a dielectric material. For example, the device isolation layer 105 may include a liner oxide layer and a liner nitride layer that conformally cover a surface of the trench, and may also include a buried oxide layer that fills the trench in which are formed the liner oxide layer and the oxide nitride layer. A top surface of the device isolation layer 105 may be substantially coplanar with the first surface 100a of the first semiconductor substrate 100. In addition, the top surface of the device isolation layer 105 may be substantially coplanar with that of the pixel isolation structure PIS. For example, the top surface of the device isolation layer 105 may be substantially coplanar with the first surface 100a of the first semiconductor substrate 100.

The first semiconductor substrate 100 may be provided thereon with first and second transfer transistors TX1 and TX2, a source follower transistor SF, and a dual conversion gain transistor DCX that are included in the photoelectric conversion circuit 10P. Therefore, the first semiconductor substrate 100 may be provided on its first surface 100a with first and second transfer gate electrodes TG1 and TG2, source follower gate electrodes SFG, and a dual conversion gain gate electrode DCGE.

For example, on the first pixel region PR1, the first transfer gate electrode TG1 may be disposed on the first surface 100a of the first semiconductor substrate 100. A first floating diffusion section FD1 may be disposed on one side of the first transfer gate electrode TG1 and may be connected to the dual conversion gain transistor DCX. The dual conversion gain gate electrode DCGE may be provided on the first surface 100a of the first semiconductor substrate 100, and first and second floating diffusion sections FD1 and FD2a may be disposed on opposite sides of the dual conversion gain gate electrode DCGE.

On the second pixel region PR2, the second transfer gate electrode TG2 may be disposed on the first surface 100a of the first semiconductor substrate 100. A third floating diffusion section FD3a may be disposed in the first semiconductor substrate 100 on one side of the second transfer gate electrode TG2.

When viewed in plan, the first and second transfer gate electrodes TG1 and TG2 may overlap portions of the first and second photoelectric conversion elements PD1 and PD2, respectively. The first and second transfer gate electrodes TG1 and TG2 may be disposed in the first semiconductor substrate 100. The first and second transfer gate electrodes TG1 and TG2 may each include a lower portion inserted into the first semiconductor substrate 100 and an upper portion that is connected to the lower portion and upwardly protrudes from the first surface 100a of the first semiconductor substrate 100. The lower portions of the first and second transfer gate electrodes TG1 and TG2 may vertically penetrate a portion of the first semiconductor substrate 100. The first and second transfer gate electrodes TG1 and TG2 may have their bottom surface located at a different level from that of the first surface 100a of the first semiconductor substrate 100. A gate dielectric layer may be interposed between the first semiconductor substrate 100 and each of the first and second transfer gate electrodes TG1 and TG2.

On the first pixel region PR1, the source follower gate electrode SFG may be provided on the first surface 100a of the first semiconductor substrate 100. Source/drain regions SDR may be disposed on opposite sides of the source follower gate electrode SFG.

Second floating diffusion sections FD2a and FD2b may be correspondingly disposed in the first and second semiconductor substrates 100 and 200. The second floating diffusion section FD2a disposed in the first semiconductor substrate 100 may be electrically connected through conductive lines ML and contact plugs CT to the second floating diffusion section FD2b disposed in the second semiconductor substrate 200.

Likewise, third floating diffusion sections FD3a and FD3b may be correspondingly disposed in the first and second semiconductor substrates 100 and 200. The third floating diffusion section FD3a disposed in the first semiconductor substrate 100 may be electrically connected through conductive lines ML and contact plugs CT to the third floating diffusion section FD3b disposed in the second semiconductor substrate 200.

As the dual conversion gain gate electrode DCGE and the source follower gate electrode SFG are disposed in the first semiconductor substrate 100, unlike the second and third floating diffusion sections FD2a, FD2b, FD3a, and FD3b, the first floating diffusion section FD1 may be disposed in only the first semiconductor substrate 100.

When the dual conversion gain transistor DCX is turned off, the image sensor may operate in the first conversion gain mode (or a high illumination mode). For example, charges generated from the first photoelectric conversion element PD1 may be stored in the first floating diffusion section FD1, and the stored charges may be transferred to the source follower gate electrode SFG through the contact plug CT and the conductive lines ML. The source follower transistor SF may generate a source-drain current in proportion to an amount of charge of the first floating diffusion section FD1 input to the source follower gate electrode SFG.

For example, when the first floating diffusion section FD1 is disposed even on the second semiconductor substrate 200, it may be required that the first transfer gate electrode TG1 disposed on the first semiconductor substrate 100 and the first floating diffusion section FD1 disposed on the second semiconductor substrate 200 be connected through conductive lines or contact plugs. Thus, the first floating diffusion section FD1 may increase in parasitic capacitance, and the first conversion gain mode may decrease in conversion gain. According to an embodiment of the present example embodiments, the dual conversion gain transistor DCX may be provided on the first semiconductor substrate 100 to allow the first floating diffusion section FD1 to reside on only the first semiconductor substrate 100, and thus it may be possible to prevent an increase in parasitic capacitance of the first floating diffusion section FD1.

Some pixel transistors RX, SX, SW1, and SW2 may be provided on the second semiconductor substrate 200. For example, the second semiconductor substrate 200 may be provided thereon with a selection transistor SX, a reset transistor RX, and first and second switching transistors SW1 and SW2 that are included in the pixel circuit 20P. Thus, the second semiconductor substrate 200 may be provided on its first surface 200a with a selection gate electrode SXG, a reset gate electrode RXG, and first and second switching gate electrodes SWG1 and SWG2.

First and second interlayer dielectric layers 110 and 210 may be disposed on each of the first and second semiconductor substrates 100 and 200, and may cover the pixel transistors RX, DCX, SF, SX, SW1, and SW2 or the first and second transfer gate electrodes TG1 and TG2. For example, the first interlayer dielectric layer 110 may cover the first surface 100a of the first semiconductor substrate 100, the first and second transfer gate electrodes TG1 and TG2, the source follower gate electrode SFG, and the dual conversion gain gate electrode DCGE. The second interlayer dielectric layer 210 may cover the first surface 200a of the second semiconductor substrate 200, the selection gate electrode SXG, the reset gate electrode RXG, and the first and second switching gate electrodes SWG1 and SWG2.

The first and second interlayer dielectric layers 110 and 210 may be provided therein with conductive lines ML, contact plugs CT, first and second bonding pads BP1 and BP2, and a capacitor CAP.

In the first and second interlayer dielectric layers 110 and 210, the conductive lines ML may be coupled to the contact plugs CT. For example, the conductive lines ML and the contact plugs CT may include metal, such as tungsten, copper, aluminum, or any alloy thereof.

The first bonding pad BP1 may be disposed at top of the first interlayer dielectric layer 110 positioned on the first semiconductor substrate 100, and the second bonding pad BP2 may be disposed at top of the second interlayer dielectric layer 210 positioned on the second semiconductor substrate 200. The first and second interlayer dielectric layers 110 and 210 may be in contact with each other, and thus the first bonding pad BP1 disposed at top of the first interlayer dielectric layer 110 may be in contact with the second bonding pad BP2 disposed at top of the second interlayer dielectric layer 210.

The first and second bonding pads BP1 and BP2 may be connected through the contact plugs CT and the conductive lines ML to the first and second transfer gate electrodes TG1 and TG2, the floating diffusion sections FD1, FD2a, FD2b, FD3a, and FD3b, and the source/drain regions SDR.

As the first and second bonding pads BP1 and BP2 are electrically connected to each other, the third floating diffusion section FD3a disposed on the first semiconductor substrate 100 may be electrically connected to the third floating diffusion section FD3b disposed on the second semiconductor substrate 200. Likewise, the second floating diffusion section FD2a disposed on the first semiconductor substrate 100 may be electrically connected to the second floating diffusion section FD2b disposed on the second semiconductor substrate 200.

A hybrid bonding method may be employed to directly and electrically connect the first bonding pads BP1 to the second bonding pads BP2. In this description, the term “hybrid bonding” may denote that two components of the same kind are merged at an interface therebetween. For example, when the first and second bonding pads BP1 and BP2 are formed of copper, a copper-to-copper bonding may be employed to physically and electrically connect the first and second bonding pads BP1 and BP2 to each other. In addition, a dielectric-to-dielectric bonding may be employed to bond a surface of the first interlayer dielectric layer 110 of the photoelectric conversion circuit layer 10 to a surface of the second interlayer dielectric layer 210 of the pixel circuit layer 20.

Referring to FIG. 5A, the capacitor CAP may be disposed in the second interlayer dielectric layer 210. As discussed above, the capacitor CAP may be a capacitor (see C_{FD} of FIGS. 3A and 3B) connected between the second switching transistor SW2 and the pixel power voltage V_{DD}. For example, the capacitor CAP may be a metal-oxide-semiconductor (MOS) capacitor, a metal-insulator-semiconductor (MIS) capacitor, or a metal-insulator-metal (MIM) capacitor.

A source/drain region SDR of the second switching transistor SW2 may be connected to one side of the capacitor CAP. Although not shown in FIG. 5A, another side of the capacitor CAP may be connected to the pixel power voltage (see V_{DD} of FIG. 3A).

A planarized dielectric layer 310 may cover the second surface 100b of the first semiconductor substrate 100. The planarized dielectric layer 310 may be formed of a transparent dielectric material and may include a plurality of layers. The planarized dielectric layer 310 may be formed of a dielectric material whose refractive index is different from that of the first semiconductor substrate 100. The planarized dielectric layer 310 may include one or more of metal oxide and silicon oxide.

A grid structure 320 may be disposed on the planarized dielectric layer 310. Similar to the pixel isolation structure PIS, the grid structure 320 may have a grid or mesh shape when viewed in plan. When viewed in plan, the grid structure 320 may overlap the pixel isolation structure PIS. For example, the grid structure 320 may include first portions that extend in the first direction D1 and second portions that extend in the second direction D2 while running across the first portions. The grid structure 320 may have a width substantially the same as or less than a minimum width of the pixel isolation structure PIS.

The grid structure 320 may include one or more of a conductive pattern and a low-refractive pattern. The conductive pattern may include a metallic material, such as titanium, tantalum, or tungsten. The low-refractive pattern may be formed of a material whose refractive index is less than that of the conductive pattern. The low-refractive pattern may be formed of an organic material and may have a refractive index of about 1.1 to about 1.3. For example, the grid structure 320 may be a polymeric layer including silica nano-particles.

The planarized dielectric layer 310 may be provided thereon with a protection layer 330 having a substantially uniform thickness that covers a surface of the grid structure 320. The protection layer 330 may be a single or multiple layer including, for example, at least one selected from an aluminum oxide layer and a silicon carbon oxide layer.

A color filter 340 may be formed corresponding to each unit pixel UP. For example, the first and second pixel regions PR1 and PR2 of each unit pixel UP may share one color filter 340. The first and second photoelectric conversion elements PD1 and PD2 may convert light released from the color filter 340 to an electrical signal.

The color filters 340 may fill spaces defined by the grid structure 320. Based on the unit pixel UP, the color filter 340 may include one of red, green, and blue color filters or one of magenta, cyan, and yellow color filters. Alternatively, one or more of the color filters 340 may include a white color filter or an infrared filter.

Microlenses 350 may be disposed on the color filters 340. The microlenses 350 may each have a convex shape with a certain curvature radius. The microlenses 350 may be formed of a light-transmitting resin. The color filters 340 may be provided thereon with the microlenses 350 that correspond to the first and second pixel regions PR1 and PR2.

As a sum of light-receiving areas of the first photoelectric conversion elements PD1 is greater than a sum of light-receiving areas of the second photoelectric conversion elements PD2, areas of the microlenses 350 disposed on the first photoelectric conversion elements PD1 may be greater than areas of the microlenses 350 disposed on the second photoelectric conversion elements PD2. A curvature radius of the microlens 350 disposed on the first photoelectric conversion element PD1 may be different from a curvature radius of the microlens 350 disposed on the second photoelectric conversion element PD2.

FIGS. 5B and 5C illustrate cross-sectional views showing an image sensor according to some example embodiments. For brevity of description, the same technical features of the image sensor discussed above with reference to FIGS. 3A, 4A, and 5A will be omitted, and a difference thereof will be explained.

Referring to FIGS. 3A and 5B, first and second capacitors CAP1 and CAP2 may be respectively disposed in the first and second interlayer dielectric layers 110 and 210. For example, the first capacitor CAP1 may be disposed in the first interlayer dielectric layer 110, and the second capacitor CAP2 may be disposed in the second interlayer dielectric layer 210.

A first electrode CAP2_a of the second capacitor CAP2 may be connected to the source/drain region SDR of the second switching transistor SW2. Although not shown, a second electrode CAP2_b of the second capacitor CAP2 may be connected to the pixel power voltage V_{DD}.

The first capacitor CAP1 and the second capacitor CAP2 may be electrically connected to each other. For example, a first electrode CAP1_a of the first capacitor CAP1 and the first electrode CAP2_a of the second capacitor CAP2 may be electrically connected through the contact plugs CT, the conductive lines ML, and the first and second bonding pads BP1 and BP2. Likewise, a second electrode CAP1_b of the first capacitor CAP1 and the second electrode CAP2_b of the second capacitor CAP2 may be electrically connected through the contact plugs CT, the conductive lines ML, and the first and second bonding pads BP1 and BP2.

According to some example embodiments, even though the first and second capacitors CAP1 and CAP2 have small sizes due to small sizes of the unit pixels UP, the first and second capacitors CAP1 and CAP2 may be connected in parallel to each other to secure a total capacitance.

Referring to FIG. 5C, the first semiconductor substrate 100 may be provided on its first surface 100a with the source follower gate electrode SFG, the dual conversion gain gate electrode DCGE, and the first and second transfer gate electrodes TG1 and TG2. The first interlayer dielectric layer 110 may be disposed on the first surface 100a of the first semiconductor substrate 100 to cover the source follower gate electrode SFG, the dual conversion gain gate electrode DCGE, and the first and second transfer gate electrodes TG1 and TG2. The first interlayer dielectric layer 110 may be disposed below the second semiconductor substrate 200 to contact the second surface 200b of the second semiconductor substrate 200.

The second semiconductor substrate 200 may be provided on its first surface 200a with the selection gate electrode SXG, the reset gate electrode RXG, and the first and second switching gate electrodes SWG1 and SWG2. The second interlayer dielectric layer 210 may cover the first surface 200a of the second semiconductor substrate 200, the selection gate electrode SXG, the reset gate electrode RXG, and the first and second switching gate electrodes SWG1 and SWG2. The first and second surfaces 200a and 200b of the second semiconductor substrate 200 may be respectively covered with the first and second interlayer dielectric layers 110 and 210.

The capacitor CAP may be disposed in the second interlayer dielectric layer 210, but the present example embodiments are not limited thereto. For example, the capacitor CAP may be disposed on the first interlayer dielectric layer 110, and may be electrically connected to the source/drain region SDR through the conductive lines ML, the contact plugs CT, and a through plug TP.

The through plugs TP may penetrate the second semiconductor substrate 200. Portions of the through plugs TP may be disposed in the second interlayer dielectric layer 210 on the second semiconductor substrate 200 and in the first interlayer dielectric layer 110 on the first semiconductor substrate 100.

The through plugs TP may be connected to the conductive lines ML and the contact plugs CT. The source/drain regions SDR and the floating diffusion sections FD2a, FD2b, FD3a, and FD3b in the first and second semiconductor substrates 100 and 200 may be electrically connected through the through plugs TP, the conductive lines ML, and the contact plugs CT. The through plug TP may include metal, such as tungsten, copper, aluminum, or any alloy thereof.

A through dielectric pattern TIP may surround a sidewall of the through plug TP. For example, the through dielectric pattern TIP may be disposed between the through plug TP and the second semiconductor substrate 200. A top surface of the through dielectric pattern TIP may be coplanar with the first surface 200a of the second semiconductor substrate 200, and a bottom surface of the through dielectric pattern TIP may be coplanar with the second surface 200b of the second semiconductor substrate 200. The through dielectric pattern TIP may include, for example, one or more of silicon oxide, silicon nitride, and silicon oxynitride.

The second floating diffusion section FD2a disposed in the first semiconductor substrate 100 may be electrically connected through the conductive lines ML, the contact plugs CT, and the through plug TP to the second floating diffusion section FD2b disposed in the second semiconductor substrate 200. Likewise, the third floating diffusion section FD3a disposed in the first semiconductor substrate 100 may be electrically connected through the conductive lines ML, the contact plugs CT, and the through plug TP to the third floating diffusion section FD3b disposed in the second semiconductor substrate 200.

With reference to FIGS. 3B, 4B, and 6, the following will describe an image sensor according to some example embodiments. Brevity of description, the same technical features of the image sensor discussed above with reference to FIGS. 3A, 4A, and 5A will be omitted, and a difference thereof will be explained.

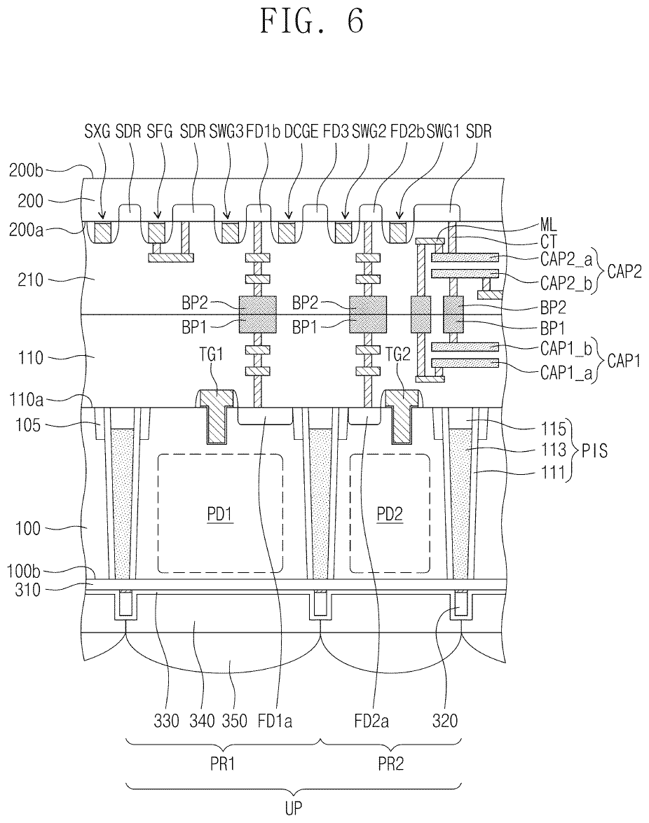

FIG. 4B illustrates a plan view showing an example of a unit pixel having a circuit configuration shown in FIG. 3B. FIG. 6 illustrates a cross-sectional view showing an image sensor according to some example embodiments.

Referring to FIGS. 3B, 4B, and 6, an image sensor may include a plurality of unit pixels UP, and each unit pixel UP may include first and second pixel regions PR1 and PR2. The first and second pixel regions PR1 and PR2 may be two-dimensionally arranged along rows and columns. When viewed in plan, each of the first and second pixel regions PR1 and PR2 may be surrounded by a pixel isolation structure PIS.

A first semiconductor substrate 100 may be provided thereon with first and second transfer transistors TX1 and TX2 of a photoelectric conversion circuit 10P. Therefore, first and second transfer gate electrodes TG1 and TG2 may be provided on a first surface 100a of the first semiconductor substrate 100.

For example, on the first pixel region PR1, the first transfer gate electrode TG1 may be disposed on the first surface 100a of the first semiconductor substrate 100. A first floating diffusion section FD1a may be disposed on one side of the first transfer gate electrode TG1.

First floating diffusion sections FD1a and FD1b may be respectively disposed in first and second semiconductor substrates 100 and 200. The first floating diffusion section FD1a disposed in the first semiconductor substrate 100 may be electrically connected through conductive lines ML, contact plugs CT, and first and second bonding pads BP1 and BP2 to the first floating diffusion section FD1b disposed in the second semiconductor substrate 200.

On the second pixel region PR2, the second transfer gate electrode TG2 may be disposed on the first surface 100a of the first semiconductor substrate 100. A third floating diffusion section FD3a may be disposed in the first semiconductor substrate 100 on one side of the second transfer gate electrode TG2.

Third floating diffusion sections FD3a and FD3b may be respectively disposed in the first and second semiconductor substrates 100 and 200. The third floating diffusion section FD3a disposed in the first semiconductor substrate 100 may be electrically connected through conductive lines ML, contact plugs CT, and first and second bonding pads BP1 and BP2 to the third floating diffusion section FD3b disposed in the second semiconductor substrate 200.

Pixel transistors DCX, SF, RX, SX, SW1, and SW2 may be provided on the second semiconductor substrate 200. For example, the second semiconductor substrate 200 may be provided thereon with a dual conversion gain transistor DCX, a source follower transistor SF, a selection transistor SX, a reset transistor RX, and first, second, and third switching transistors SW1, SW2, and SW3 that are included in a pixel circuit 20P. Therefore, the second semiconductor substrate 200 may be provided on its first surface 200a with a dual conversion gain gate electrode DCGE, a source follower gate electrode SFG, a selection gate electrode SXG, a reset gate electrode RXG, and first, second, and third switching gate electrodes SWG1, SWG2, and SWG3.

According to some example embodiments, the pixel transistors DCX, SF, RX, SX, SW1, SW2, and SW3 may be disposed not on the first semiconductor substrate 100 but on the second semiconductor substrate 200. Therefore, only the first and second transfer transistors TX1 and TX2 may be disposed on the first semiconductor substrate 100, and the unit pixel UP may have a reduced size.

A length W2 in the second direction D2 of the unit pixel UP may be equal to or less than about 2.4 μm, for example, equal to or less than about 1.8 μm. The length W2 in the second direction D2 of the unit pixel UP may indicate a distance in the second direction D2 between vertices positioned on opposite ends along the second direction D2 in the unit pixel UP. For example, referring to FIG. 4B, the length W2 in the second direction D2 may indicate a distance in the second direction D2 between a vertex PR1a (a lowermost end point in the second direction D2) of the first pixel region PR1 and a vertex PR2a (an uppermost end point in the second direction D2) of the second pixel region PR2.

However, as the dual conversion gain transistor DCX and the source follower transistor SF are disposed on the second semiconductor substrate 200, the first floating diffusion sections FD1a and FD1b may be respectively disposed on the first and second semiconductor substrates 100 and 200. Therefore, the first floating diffusion section FD1a disposed in the first semiconductor substrate 100 may be connected through the conductive lines ML and the contact plugs CT to the first floating diffusion section FD1b disposed in the second semiconductor substrate 200. As only the first and second transfer transistors TX1 and TX2 are disposed on the first semiconductor substrate 100, the unit pixel UP may have a reduced size.

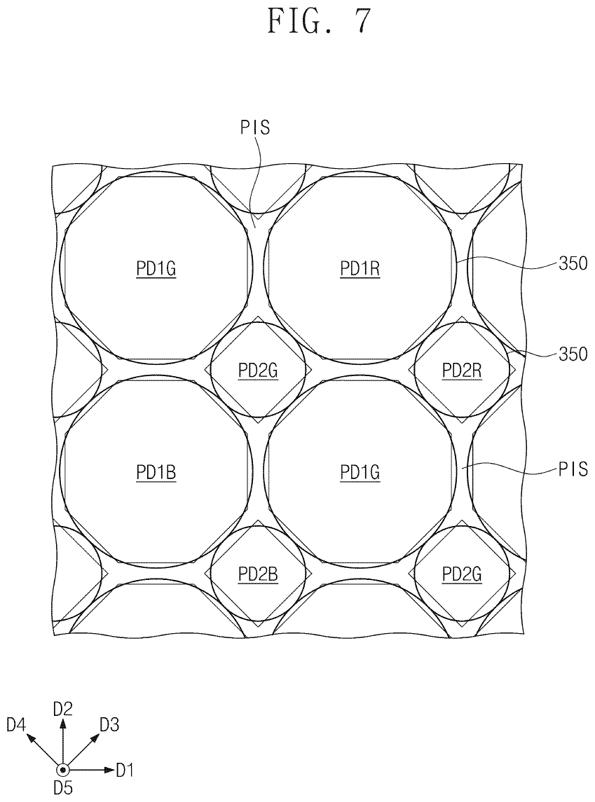

FIG. 7 illustrates a plan view showing an image sensor according to some example embodiments.

Referring to FIG. 7, each of first photoelectric conversion elements PD1R, PD1G, and PD1B may have an octagonal shape when viewed in plan. Each of the first photoelectric conversion elements PD1R, PD1G, and PD1B may have a first width in the first direction D1. The first width may be a width measured on the first surface 100a of the first semiconductor substrate 100. In addition, the first width may correspond to an interval between portions of the pixel isolation structure PIS.

Each of second photoelectric conversion elements PD2R, PD2G, and PD2B may have a tetragonal shape when viewed in plan. The second photoelectric conversion elements PD2R, PD2G, and PD2B may have their sizes less than those of the first photoelectric conversion elements PD1R, PD1G, and PD1B. In this sense, light-receiving areas of the second photoelectric conversion elements PD2R, PD2G, and PD2B may be less than those of the first photoelectric conversion elements PD1R, PD1G, and PD1B. For example, each of the second photoelectric conversion elements PD2R, PD2G, and PD2B may have a second width in the first direction D1 less than the first width. In this description, widths of two components may be compared with each other in the same direction at the same level.

When viewed in plan, each of a plurality of second photoelectric conversion elements PD2R, PD2G, and PD2B, or each of the second pixel regions PR2, may be surrounded by neighboring four first photoelectric conversion elements PD1R, PD1G, and PD1B. When viewed in plan, the second photoelectric conversion elements PD2R, PD2G, and PD2B may be two-dimensionally arranged along the first direction D1 and the second direction D2.

The first photoelectric conversion elements PD1R, PD1G, and PD1B and the second photoelectric conversion elements PD2R, PD2G, and PD2B may be alternately disposed along a first diagonal direction D3 and a second diagonal direction D4. The second photoelectric conversion elements PD2R, PD2G, and PD2B may be correspondingly disposed in the first diagonal direction D3 and the second diagonal direction D4 between the first photoelectric conversion elements PD1R, PD1G, and PD1B.

The first photoelectric conversion elements PD1R, PD1G, and PD1B and the second photoelectric conversion elements PD2R, PD2G, and PD2B may be alternately disposed along the first direction D1. The second photoelectric conversion elements PD2R, PD2G, and PD2B may be correspondingly disposed in the first direction D1 and the second direction D2 between the first photoelectric conversion elements PD1R, PD1G, and PD1B.

According to some embodiments, an arrangement of unit pixels may be highly integrated due to adjustment of the planar shapes and the first widths of the first photoelectric conversion elements PD1R, PD1G, and PD1B and due to adjustment of the planar shapes and the second widths of the second photoelectric conversion elements PD2R, PD2G, and PD2B. Therefore, the image sensor may increase in optical properties.

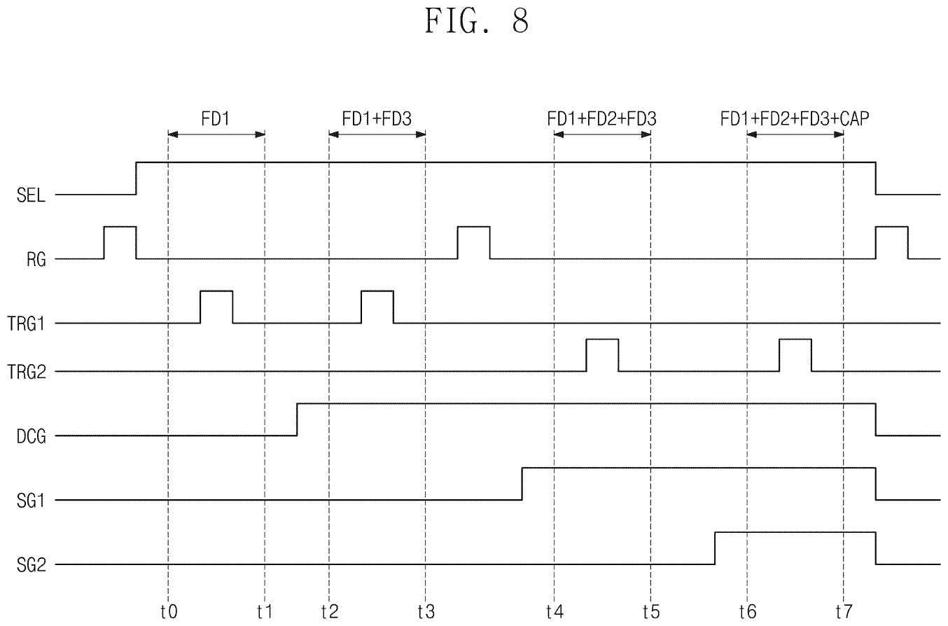

FIG. 8 illustrates a timing diagram showing an operation of an image sensor according to some example embodiments.

Referring to FIGS. 3A and 8, the reset signal RG may be activated to turn on the reset transistor RX. Thus, the first floating diffusion section FD1 may be provided with the pixel power voltage V_{DD} to discharge charges from the first floating diffusion section FD1, with the result that the first floating diffusion section FD1 may be reset (or initialized).

When the reset signal RG is activated, the first and second switching signals SG1 and SG2 may be activated to also provide the second and third floating diffusion sections FD2 and FD3 with the pixel power voltage V_{DD}. Thus, the second and third floating diffusion sections FD2 and FD3 may also be reset.

The reset signal RG may be inactivated to turn off the reset transistor RX. Thus, the first, second, and third floating diffusion sections FD1, FD2, and FD3 may become a state capable of storing charges.

Immediately after the reset transistor RX is turned off, the selection signal SEL may be activated to turn on the selection transistor SX. When the selection transistor SX is turned on, the output line V_{OUT} may output pixel signals.

At a time of t0, a first reset signal may be output which is in proportion to a potential of the first floating diffusion section FD1.

After the first reset signal is read out, a first transfer signal TRG1 may be activated to turn on the first transfer transistor TX1. Thus, in the first conversion gain mode, charges accumulated in the first photoelectric conversion element PD1 may be transferred to the first floating diffusion section FD1.

The first transfer signal TRG1 may be inactivated to turn off the first transfer transistor TX1, and at a time of t1, a first pixel signal may be output which is in proportion to a number of photo-charges accumulated in the first photoelectric conversion element PD1 in the first conversion gain mode.

After the first pixel signal is output, the dual conversion gain control signal DCG may be activated to turn on the dual conversion gain transistor DCX. Thus, the first photoelectric conversion element PD1 may operate in the second conversion gain mode whose conversion gain is less than that of the first conversion gain mode.

The turn-on of the dual conversion gain transistor DCX may output a second pixel signal as a sum of capacitance of the first and third floating diffusion sections FD1 and FD3.

After the dual conversion gain transistor DCX is turned on, at a time of t2, the first transfer signal TRG1 may be activated to re-turn on the first transfer transistor TX1. Therefore, in the second conversion gain mode, charges accumulated in the first photoelectric conversion element PD1 may be transferred to the first and third floating diffusion sections FD1 and FD3.

The first transfer signal TRG1 may be inactivated to turn off the first transfer transistor TX1, and at a time of t3, the second pixel signal may be output which is in proportion to a number of photo-charges accumulated in the first photoelectric conversion element PD1 in the second conversion gain mode. For example, the second pixel signal may be in proportion to amounts of charge stored in the first and third floating diffusion sections FD1 and FD3.

The reset signal RG may be activated again to turn on the reset transistor RX. Therefore, charges may be discharged from the first and second floating diffusion sections FD1 and FD2, and accordingly the first and second floating diffusion sections FD1 and FD2 may be reset.

After the first and second floating diffusion sections FD1 and FD2 are reset, the first switching signal SG1 may be activated to turn on the first switching transistor SW1. Thus, a third pixel signal may be output which corresponds to a sum of capacitance of the first, second, and third floating diffusion sections FD1, FD2, and FD3. Accordingly, the image sensor may operate in a third conversion gain mode whose conversion gain is less than that of the second conversion gain mode.

At a time of t4, a second transfer signal TRG2 may be activated to turn on the second transfer transistor TX2. Therefore, in the third conversion gain mode, charges accumulated in the second photoelectric conversion element PD2 may be transferred to the first, second, and third floating diffusion sections FD1, FD2, and FD3.

The second transfer signal TRG2 may be inactivated to turn off the second transfer transistor TX2, and at a time of t5, a third pixel signal may be output which is in proportion to a number of photo-charges accumulated in the second photoelectric conversion element PD2. For example, the third pixel signal may be in proportion to amounts of charge stored in the first, second, and third floating diffusion sections FD1, FD2, and FD3.

After the third pixel signal is output, the second switching signal SG2 may be activated to turn on the second switching transistor SW2. Thus, a fourth pixel signal may be output which corresponds to a sum of capacitance of the first, second, and third floating diffusion sections FD1, FD2, and FD3 and the capacitor CAP. Accordingly, the image sensor may operate in a fourth conversion gain mode whose conversion gain is less than that of the third conversion gain mode.

At a time of t6, the second transfer signal TRG2 may be activated to turn on the second transfer transistor TX2. Therefore, in the fourth conversion gain mode, charges accumulated in the second photoelectric conversion element PD2 may be transferred to the first, second, and third floating diffusion sections FD1, FD2, and FD3 and the capacitor CAP.

The second transfer signal TRG2 may be inactivated to turn off the second transfer transistor TX2, and at a time of t7, a fourth pixel signal may be output which is in proportion to a number of photo-charges accumulated in the second photoelectric conversion element PD2. For example, the fourth pixel signal may be in proportion to amounts of charge stored in the first, second, and third floating diffusion sections FD1, FD2, and FD3 and the capacitor CAP.

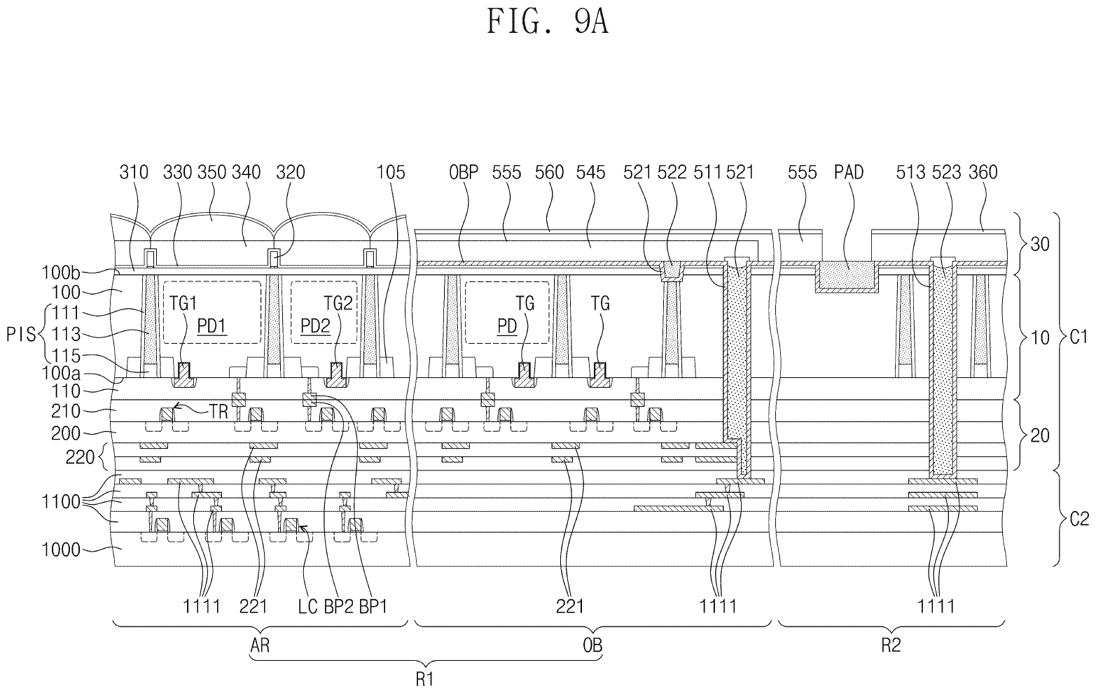

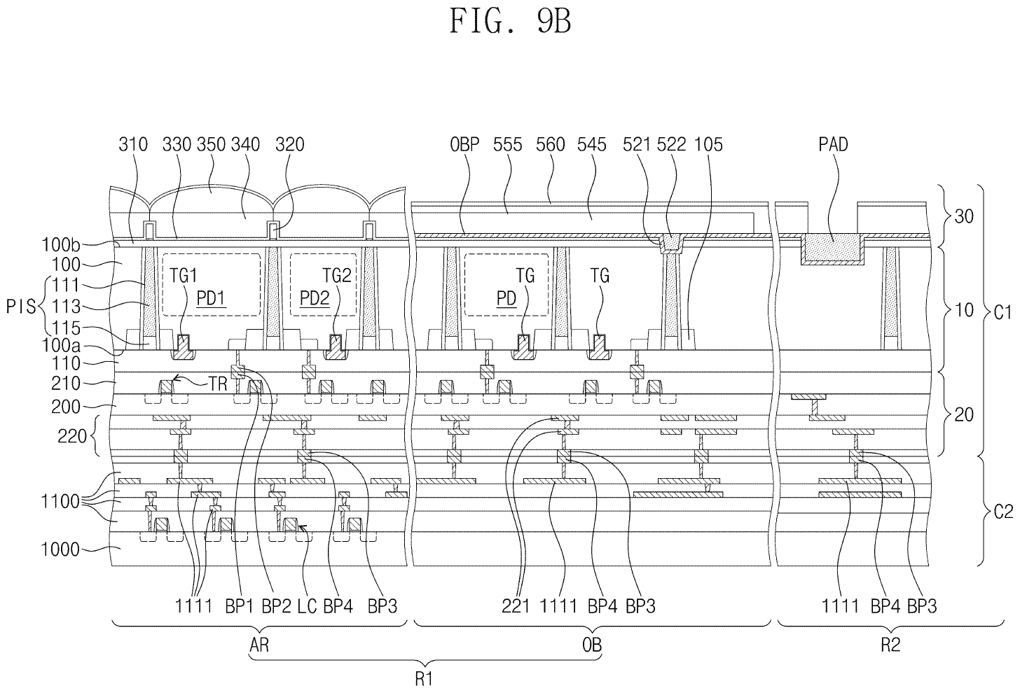

FIGS. 9A and 9B illustrate cross-sectional views showing an image sensor according to some example embodiments.

Referring to FIG. 9A, an image sensor may include a sensor chip C1 and a logic chip C2. The sensor chip C1 may include a pixel array zone R1 and a pad zone R2.

As discussed above, the pixel array zone R1 may include a plurality of unit pixels that are two-dimensionally arranged along the first direction D1 and the second direction D2 that intersect each other. Each of the unit pixels may include first and second photoelectric conversion elements and pixel transistors. Each unit pixel of the pixel array zone R1 may output an electrical signal generated from incident light.

The pixel array zone R1 may include a light-receiving region AR and a light-shielding region OB. When viewed in plan, a light-shielding region OB may surround the light-receiving region AR. For example, when viewed in plan, the light-shielding region OB may be disposed on upside, downside, left-side, and right-side of the light-receiving region AR. The light-shielding region OB may include reference pixels on which no light is incident, and amounts of charge sensed in the unit pixels of the light-receiving region AR may be compared with a reference amounts of charge occurring at reference pixels, which may result in calculation of magnitude of electrical signals sensed in the unit pixels.

The pad zone R2 may include a plurality of conductive pads PAD used for input and output of control signals and photoelectric conversion signals. For easy connection with external devices, when viewed in plan, the pad zone R2 may surround the pixel array zone R1. The conductive pads PAD may allow an external device to receive electrical signals generated from the unit pixels.

The sensor chip C1 may include a photoelectric conversion circuit layer 10 between a pixel circuit layer 20 and an optical transmission layer 30. As discussed above, the photoelectric conversion circuit layer 10 of the sensor chip C1 may include a first semiconductor substrate 100, a pixel isolation structure PIS that defines pixel regions, and first and second photoelectric conversion elements PD1 and PD2. As discussed above, the pixel circuit layer 20 may include a second semiconductor substrate 200, pixel transistors TR provided on at least a portion of the second semiconductor substrate 200, and a second interlayer dielectric layer 210. On the light-receiving region AR, the sensor chip C1 may have technical features the same as those of the image sensor discussed above.

The pixel isolation structure PIS may extend from the light-receiving region AR toward the light-shielding region OB. A portion of the pixel isolation structure PIS may be electrically connected to a contact plug 522 on the light-shielding region OB.

A planarized dielectric layer 310 may extend from the light-receiving region AR toward the light-shielding region OB and the pad zone R2.

On the light-shielding region OB, a light-shielding pattern OBP may be disposed on the planarized dielectric layer 310. The light-shielding pattern OBP may not allow light to travel toward photoelectric conversion elements PD provided on the light-shielding region OB. On reference pixel regions of the light-shielding region OB, the photoelectric conversion elements PD may output noise signals without outputting photoelectric signals. The noise signals may be generated from electrons produced due to heat or dark current. The light-shielding pattern OBP may include metal, such as tungsten, copper, aluminum, or any alloy thereof.

A filtering layer 545 may be provided on the light-shielding pattern OBP. The filtering layer 545 may block light whose wavelength is different from that of light produced from the color filters 340. For example, the filtering layer 545 may block an infrared ray. The filtering layer 545 may include a blue color filter, but the present example embodiments are not limited thereto.

On the light-shielding region OB, a first through conductive pattern 511 may penetrate the first semiconductor substrate 100 to come into electrical connection with a metal line 221 of the pixel circuit layer 20 and with a wiring structure 1111 of the logic chip C2. The first through conductive pattern 511 may have a first bottom surface and a second bottom surface that are located at different levels. A first buried pattern 521 may be provided in the first through conductive pattern 511. The first buried pattern 521 may include a low-refractive material and may have dielectric properties.

On the pad zone R2, conductive pads PAD may be provided on a second surface 100b of the first semiconductor substrate 100. The conductive pads PAD may be buried in the second surface 100b of the first semiconductor substrate 100. For example, on the pad zone R2, the conductive pads PAD may be provided in a pad trench formed on the second surface 100b of the first semiconductor substrate 100. The conductive pads PAD may include metal, such as aluminum, copper, tungsten, titanium, tantalum, or any alloy thereof. In a mounting process of the image sensor, bonding wires may be bonded to the conductive pads PAD. The conductive pads PAD may be electrically connected through the bonding wires to an external device.

On the pad zone R2, a second through conductive pattern 513 may penetrate the first semiconductor substrate 100 to come into electrical connection with the wiring structure 1111 of the logic chip C2. The second through conductive pattern 513 may extend onto the second surface 100b of the first semiconductor substrate 100 to come into electrical connection with the conductive pad PAD. A portion of the second through conductive pattern 513 may cover a bottom surface and a sidewall of the conductive pad PAD. A second buried pattern 523 may be provided in the second through conductive pattern 513. The second buried pattern 523 may include a low-refractive material and may have dielectric properties. On the pad zone R2, the pixel isolation structure PIS may be provided around the second through conductive pattern 513.

The logic chip C2 may include a third semiconductor substrate 1000, logic circuits LC, wiring structures 1111 connected to the logic circuits LC, and logic interlayer dielectric layers 1100. An uppermost one of the logic interlayer dielectric layers 1100 may be coupled to the pixel circuit layer 20 of the sensor chip C1. The logic chip C2 may be electrically connected to the sensor chip C1 through the first through conductive pattern 511 and the second through conductive pattern 513.

In an embodiment, it is described above that the sensor chip C1 and the logic chip C2 are electrically connected through the first and second through conductive patterns 511 and 513, but the present example embodiments are not limited thereto.

According to the embodiment depicted in FIG. 9B, the sensor chip C1 and the logic chip C2 may be electrically connected due to direct contact between third and fourth bonding pads BP3 and BP4 provided at uppermost metal layers of the sensor chip C1 and the logic chip C2.

For example, an image sensor may be configured such that the sensor chip C1 may include the third bonding pads BP3 provided at the uppermost metal layer of the pixel circuit layer 20, and that the logic chip C2 may include the fourth bonding pads BP4 provided at the uppermost metal layer of the wiring structure 1111. The third and fourth bonding pads BP3 and BP4 may include, for example, at least one selected from tungsten (W), aluminum (Al), copper (Cu), tungsten nitride (WN), tantalum nitride (TaN), and titanium nitride (TiN).

A hybrid bonding method may be employed to directly and electrically connect the third bonding pads BP3 of the sensor chip C1 to the fourth bonding pads BP4 of the logic chip C2. In this description, the term “hybrid bonding” may denote that two components of the same kind are merged at an interface therebetween. For example, when the third and fourth bonding pads BP3 and BP4 are formed of copper (Cu), a copper-to-copper bonding may be employed to physically and electrically connect the third and fourth bonding pads BP3 and BP4 to each other. In addition, a dielectric-to-dielectric bonding may be adopted to couple a surface of a dielectric layer included in the sensor chip C1 to a surface of a dielectric layer included in the logic chip C2.

According to some example embodiments, pixel transistors may be disposed distributed on a first semiconductor substrate and a second semiconductor substrate. A high dynamic range (HDR) may be secured due to some pixel transistors and first and second transfer gate electrodes disposed on the first semiconductor substrate, and in addition, a size of a unit pixel may be reduced due to some pixel transistors disposed on the second semiconductor substrate.

Although some example embodiments have been discussed with reference to accompanying figures, it will be understood that various changes in form and details may be made therein without departing from the spirit and scope of the present example embodiments. It therefore will be understood that the embodiments described above are just illustrative but not limitative in all aspects.

In various example embodiments herein, reference may have been made to various circuit elements, including but not limited to capacitors, resistor, inductors, switches, amplifiers, comparators, filters, and transistors. Various different types of digital, analog, active and/or passive components are available for use in implementing the example embodiments. For example, as discussed above, pseudo-resistors can be substituted for passive resistors. Additionally various different transistor types can be used depending on the implementation, whether positive or negative logic is used, manufacturing processes employed, or the like. Furthermore, unless specifically stated otherwise herein, there are many available types of filters, comparators, switches, and the like that can be used to implement the example embodiments.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the term “same” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When either of the terms “about” or “substantially” is used in this specification in connection with a numerical value, it is intended that the associated numerical value includes a manufacturing or operational tolerance (e.g., ±10%) around the stated numerical value. Moreover, when the word “generally” or “substantially” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

What is claimed is:

1. An image sensor, comprising:
a first semiconductor substrate that includes a first pixel region and a second pixel region;
a first photoelectric conversion element on the first pixel region;
a second photoelectric conversion element on the second pixel region;
a first floating diffusion section on the first pixel region;
a second floating diffusion section on the second pixel region;
a first transfer gate electrode between the first photoelectric conversion element and the first floating diffusion section;
a second transfer gate electrode between the second photoelectric conversion element and the second floating diffusion section;
a second semiconductor substrate on the first semiconductor substrate; and
a plurality of pixel transistors connected to the first and second photoelectric conversion elements,
wherein a width of the second photoelectric conversion element is less than a width of the first photoelectric conversion element, and
wherein at least one of the pixel transistors is on the second semiconductor substrate.

2. The image sensor of claim 1, wherein one or more of the plurality of pixel transistors are on the first pixel region of the first semiconductor substrate.

3. The image sensor of claim 1, wherein the plurality of pixel transistors include:
a dual conversion gain transistor on the first semiconductor substrate and connected to the first floating diffusion section; and
a source follower transistor on the first semiconductor substrate.

4. The image sensor of claim 3, wherein the plurality of pixel transistors include:
a selection transistor on the second semiconductor substrate and connected to the source follower transistor;
a reset transistor on the second semiconductor substrate and connected to the dual conversion gain transistor;
a first switching transistor on the second semiconductor substrate and connected to the second floating diffusion section; and
a second switching transistor on the second semiconductor substrate and connected to the second floating diffusion section.

5. The image sensor of claim 1, wherein the plurality of pixel transistors include:
a dual conversion gain transistor on the second semiconductor substrate and connected to the first floating diffusion section; and
a source follower transistor on the second semiconductor substrate.

6. The image sensor of claim 5, wherein the plurality of pixel transistors include:
a selection transistor on the second semiconductor substrate and connected to the source follower transistor;
a reset transistor on the second semiconductor substrate and connected to the dual conversion gain transistor;
a first switching transistor on the second semiconductor substrate and connected to the dual conversion gain transistor; and
a second switching transistor on the second semiconductor substrate and connected to the second floating diffusion section.

7. The image sensor of claim 5, wherein the plurality of pixel transistors further include a third switching transistor on the second semiconductor substrate and connected to the first floating diffusion section and the source follower transistor.

8. The image sensor of claim 1, further comprising a capacitor connected between the second floating diffusion section and a pixel power voltage.

9. The image sensor of claim 1, further comprising:
a first capacitor in a first interlayer dielectric layer on the first semiconductor substrate; and
a second capacitor in a second interlayer dielectric layer on the second semiconductor substrate,
wherein the first and second capacitors are connected in parallel to each other.

10. The image sensor of claim 1, wherein each of the first and second transfer gate electrodes vertically penetrates a portion of the first semiconductor substrate.

11. The image sensor of claim 1, further comprising a pixel isolation structure in the first semiconductor substrate and between the first photoelectric conversion element and the second photoelectric conversion element.

12. The image sensor of claim 1, further comprising:
a first interlayer dielectric layer on the first semiconductor substrate and covering the first and second transfer gate electrodes;
a second interlayer dielectric layer on the second semiconductor substrate and covering the at least one of the plurality of pixel transistors;
a first bonding pad in the first interlayer dielectric layer; and
a second bonding pad in the second interlayer dielectric layer and in contact with the first bonding pad.

13. The image sensor of claim 1, further comprising:
a first interlayer dielectric layer on the first semiconductor substrate and covering the first and second transfer gate electrodes;
a second interlayer dielectric layer on the second semiconductor substrate and covering the at least one of the plurality of pixel transistors; and
a through plug that penetrates the second semiconductor substrate and is connected to conductive lines of the first and second interlayer dielectric layers.

14. An image sensor, comprising:
a photoelectric conversion circuit layer that includes first and second photoelectric conversion elements on a first semiconductor substrate;
a pixel circuit layer that includes a second semiconductor substrate and is on the photoelectric conversion circuit layer; and
a logic circuit layer on the pixel circuit layer and including logic circuits on a third semiconductor substrate,
wherein the photoelectric conversion circuit layer includes
a dual conversion gain transistor on the first semiconductor substrate and connected between a first floating diffusion section and a third floating diffusion section;
a source follower transistor on the first semiconductor substrate and connected to the first floating diffusion section;
a first transfer gate electrode between the first photoelectric conversion element and the first floating diffusion section; and
a second transfer gate electrode between the second photoelectric conversion element and a second floating diffusion section,
wherein the pixel circuit layer includes:
a reset transistor on the second semiconductor substrate and connected to the third floating diffusion section;
a first switching transistor on the second semiconductor substrate and connected to the dual conversion gain transistor; and
a second switching transistor on the second semiconductor substrate and connected to the second floating diffusion section,
wherein a width of the second photoelectric conversion element is less than a width of the first photoelectric conversion element.

15. The image sensor of claim 14, further comprising a capacitor between the second switching transistor and a pixel power voltage.

16. The image sensor of claim 14, further comprising:
a first capacitor in a first interlayer dielectric layer on the first semiconductor substrate; and
a second capacitor in a second interlayer dielectric layer on the second semiconductor substrate,
wherein the first and second capacitors are connected in parallel to each other.

17. The image sensor of claim 14, wherein
the photoelectric conversion circuit layer includes a plurality of first bonding pads connected to the first and second transfer gate electrodes, and
the pixel circuit layer includes a plurality of second bonding pads in contact with the first bonding pads.

18. An image sensor, comprising:
a photoelectric conversion circuit layer that includes first and second photoelectric conversion elements on a first semiconductor substrate;
a pixel circuit layer that includes a second semiconductor substrate and is on the photoelectric conversion circuit layer; and
a logic circuit layer on the pixel circuit layer and including logic circuits on a third semiconductor substrate,
wherein the photoelectric conversion circuit layer includes
a first transfer gate electrode between the first photoelectric conversion element and the first floating diffusion section; and
a second transfer gate electrode between the second photoelectric conversion element and the second floating diffusion section,
wherein the pixel circuit layer includes:
a dual conversion gain transistor on the second semiconductor substrate and connected between the first floating diffusion section and a third floating diffusion section;
a source follower transistor on the second semiconductor substrate;
a reset transistor on the second semiconductor substrate and connected to the third floating diffusion section;
a first switching transistor on the second semiconductor substrate and connected to the dual conversion gain transistor;
a second switching transistor on the second semiconductor substrate and connected to the second floating diffusion section; and
a third switching transistor on the second semiconductor substrate and connected to the source follower transistor and the first floating diffusion section,
wherein a width of the second photoelectric conversion element is less than a width of the first photoelectric conversion element.

19. The image sensor of claim 18, further comprising:
a first capacitor in a first interlayer dielectric layer on the first semiconductor substrate; and
a second capacitor in a second interlayer dielectric layer on the second semiconductor substrate,
wherein the first and second capacitors are connected in parallel to each other.

20. The image sensor of claim 18, wherein
the photoelectric conversion circuit layer includes a plurality of first bonding pads connected to the first and second transfer gate electrodes, and
the pixel circuit layer includes a plurality of second bonding pads in contact with the first bonding pads.
